(19) United States
(12) Patent Application Publication
(10) Pub. No.: US 2026/0155070 A1
(43) Pub. Date: Jun. 4, 2026

(54) INFORMATION PROCESSING SYSTEM AND INFORMATION PROCESSING METHOD

(71) Applicant: SONY GROUP CORPORATION, TOKYO (JP)

(72) Inventor: NOBUTANE CHIBA, TOKYO (JP)

(21) Appl. No.: 18/702,167

(22) PCT Filed: Oct. 13, 2022
(86) PCT No.: PCT/JP2022/038160

§ 371 Date: Apr. 17, 2024

(30) Foreign Application Priority Data
Oct. 26, 2021 (JP) 2021-174620

(51) Int. Cl. G09G 3/02; G09G 3/32; G09G 5/00; G09G 5/36

(52) U.S. Cl. CPC G09G 3/02; G09G 3/32; G09G 5/008; G09G 5/36

(57) ABSTRACT

The present technology relates to an information processing system and an information processing method that allow a reduction in power consumption.

A picture being displayed on a display unit is acquired, the picture thus acquired is divided into section pictures, each of the section pictures being displayed in a corresponding one of a plurality of sections obtained by dividing the display unit, an amount of change of each of the section pictures being displayed in a corresponding one of the plurality of sections or luminance of each of the section pictures is determined, and a frequency of scanning related to light emission of pixels corresponding to each of the section pictures is set on the basis of the amount of change or the luminance.

### TECHNICAL FIELD

The present technology relates to an information processing system and an information processing method, and more particularly, to an information processing system and an information processing method that allow a reduction in power consumption.

### BACKGROUND ART

Patent Document 1 discloses a display device that causes each pixel of a display panel to emit light multiple times during one frame period by an active PWM drive method.

### CITATION LIST

### Patent Document

Patent Document 1: WO 2018/164105 A

### SUMMARY OF THE INVENTION

### Problems to be Solved by the Invention

For example, in a passive LED display, repeated scanning during one frame period of a picture being displayed causes pixels to repeatedly emit light, and if the frequency of scanning can be reduced without deteriorating quality of the picture being displayed, power consumption can be reduced.

The present technology has been made in view of such circumstances, and it is therefore an object of the present technology to reduce power consumption.

### Solutions to Problems

An information processing system of the present technology is an information processing system including: an acquisition unit configured to acquire a picture being displayed on a display unit; a signal processing unit configured to divide the picture acquired by the acquisition unit into section pictures, each of the section pictures being displayed in a corresponding one of a plurality of sections obtained by dividing the display unit; a determination unit configured to determine an amount of change of the section picture being displayed in each of the plurality of sections or luminance of the section picture; and a setting unit configured to set a frequency of scanning related to light emission of pixels corresponding to each of the section pictures on the basis of the amount of change or the luminance.

An information processing method of the present technology is an information processing method of an information processing system including an acquisition unit, a signal processing unit, a determination unit, and a setting unit, the information processing method including: causing the acquisition unit to acquire a picture being displayed on a display unit; causing the signal processing unit to divide the picture acquired by the acquisition unit into section pictures, each of the section pictures being displayed in a corresponding one of a plurality of sections obtained by dividing the display unit; causing the determination unit to determine an amount of change of the section picture being displayed in each of the plurality of sections or luminance of the section picture; and causing the setting unit to set a frequency of scanning related to light emission of pixels corresponding to each of the section pictures on the basis of the amount of change or the luminance.

In the present technology, a picture being displayed on the display unit is acquired, the picture thus acquired is divided into section pictures, each of the section pictures being displayed in a corresponding one of a plurality of sections obtained by dividing the display unit, an amount of change of each of the section pictures being displayed in a corresponding one of the plurality of sections or luminance of each of the section pictures is determined, and a frequency of scanning related to light emission of pixels corresponding to each of the section pictures is set on the basis of the amount of change or the luminance.

### BRIEF DESCRIPTION OF DRAWINGS

FIG. 1 is a diagram for describing a configuration example of a display system of the present disclosure.

FIG. 2 is a diagram for describing a configuration example of a video wall controller and a display unit in FIG. 1.

FIG. 3 is a diagram for describing a configuration example of an LED array.

FIG. 4 is a diagram for describing a screen configuration of a video wall.

FIG. 5 is a diagram for describing a configuration related to display control of a Cabinet.

FIG. 6 is a diagram illustrating a configuration of the LED array (driver cover range).

FIG. 7 is a diagram for describing normal scanning control for the LED array performed by an LED driver.

FIG. 8 is a diagram illustrating an example of a picture supplied to the video wall controller as picture data.

FIG. 9 is a diagram illustrating a region where an amount of change in image is determined according to the present technology.

FIG. 10 is a block diagram illustrating extracted components, according to the present technology, of the display system.

FIG. 11 is a diagram for describing transition from the normal scanning control to power-saving scanning control for the LED array.

FIG. 12 is a flowchart illustrating a procedure of processing of changing the frequency of scanning of the LED array performed by a clock conversion unit.

FIG. 13 is a diagram for describing a difference in processing load due to a difference in size of a still image determination section.

### MODE FOR CARRYING OUT THE INVENTION

Hereinafter, an embodiment of the present technology will be described with reference to the drawings.

### Embodiment of Display System to Which Present Technology is Applied

The present disclosure relates to a technology applicable to a direct-view light emitting diode (LED) display. In the present disclosure, a direct-view LED display to which the present technology is applied will be described as an embodiment of a display to which the present technology is applied.

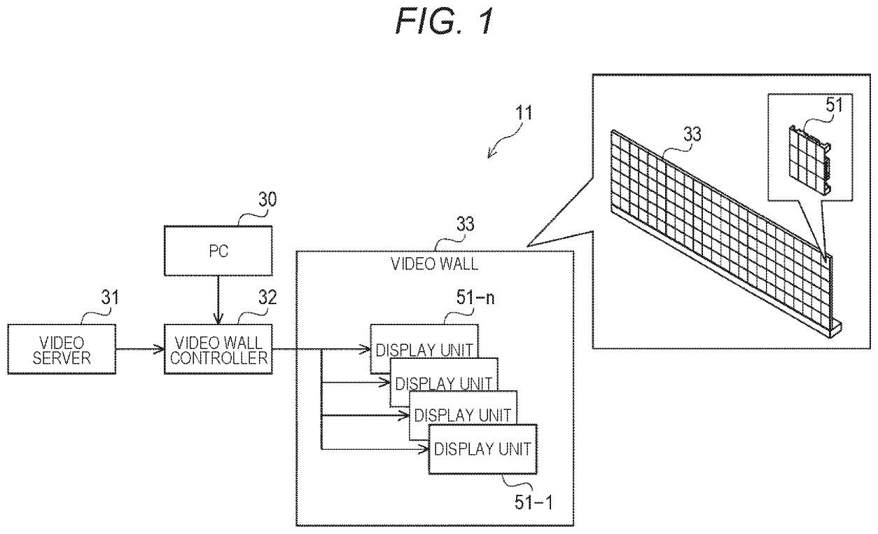

A display system 11 in FIG. 1 includes a plurality of display units arranged in a tiled layout, and displays video content on a large display.

More specifically, the display system 11 includes a personal computer (PC) 30, a video server 31, a video wall controller 32, and a video wall 33.

The personal computer (PC) 30 is a general-purpose computer, and the PC 30 receives the input of user operation and supplies a command corresponding to a detail of the operation to the video wall controller 32. The PC 30 is mainly used for controlling the video wall controller 32. The processing in the PC 30 may be performed by the video wall controller 32, and an input unit with which the user provides operation input may be provided in the video wall controller 32.

The video server 31 includes, for example, a server computer or the like, and supplies picture signal data such as video content (picture data representing a picture being displayed on a display) to the video wall controller 32. The device that supplies the picture data to the video wall controller 32 may be a video camera or any type of reproduction device rather than the server computer.

The video wall controller 32 operates in accordance with the command supplied from the PC 30, and distributes the picture data supplied from the video server 31 to display units 51-1 to 51-n (n represents the number of display units) constituting the video wall 33 to cause the display units 51-1 to 51-n to display the picture data.

Note that, in a case where it is not necessary to distinguish the display units 51-1 to 51-n, the display units 51-1 to 51-n are simply referred to as display unit 51. The display unit 51 is a device that controls display in each of a plurality of sections, the plurality of sections each being referred to as Cabinet 202 to be described later and constituting a screen of the video wall 33, and the display unit 51 is also referred to as display cabinet or cabinet.

As illustrated in the upper right part of FIG. 1, the video wall 33 includes the display units 51-1 to 51-n arranged in a tiled layout, the display units 51-1 to 51-n each having pixels including LEDs arranged in an array, and images individually displayed by the display units 51 are combined in a tiled layout, so that one entire image is displayed on the video wall 33.

The video wall controller 32 performs predetermined signal processing on the picture data supplied from the video server 31, distributes and supplies the resultant picture data to the display units 51-1 to 51-n in accordance with the arrangement of the display units 51-1 to 51-n, controls their respective displays of the display units 51-1 to 51-n, and controls the video wall 33 to display one entire image.

Note that the video wall controller 32 and the video wall 33 may be integrated with each other, or may be integrated into a display device (information processing system). Note that, in the present specification, a system means an assembly of a plurality of components (devices, modules (parts), and the like), and it does not matter whether or not all the components are located in the same housing. Therefore, a plurality of devices stored in different housings and connected over a network, and a single device including a plurality of modules stored in one housing are both regarded as systems.

### Detailed Configuration of Video Wall Controller and Display Unit

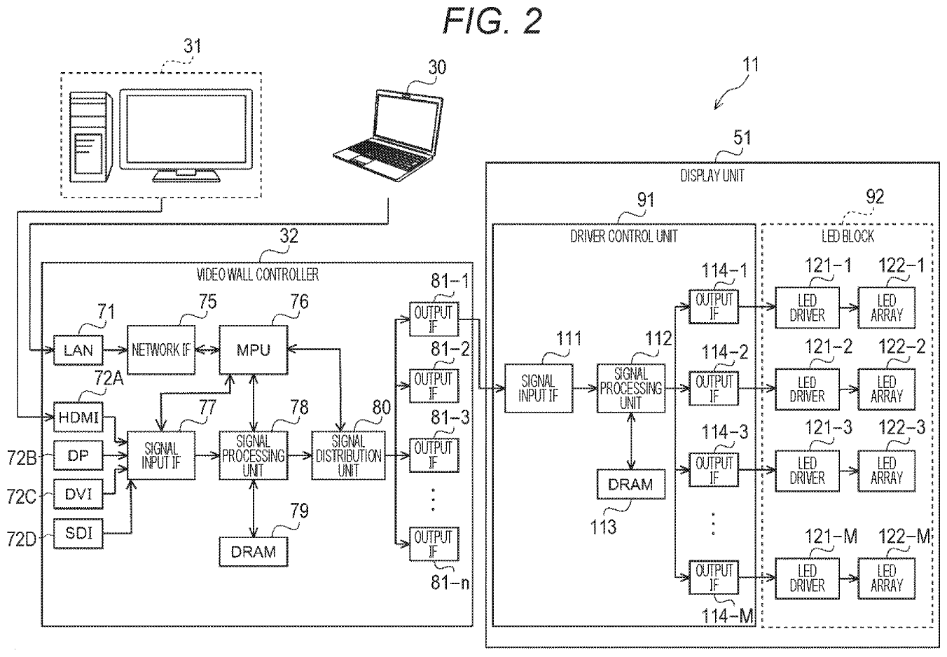

Next, a detailed configuration example of the video wall controller 32 and the display unit 51 will be described with reference to FIG. 2.

The video wall controller 32 includes a local area network (LAN) terminal 71, a high definition multimedia interface (HDMI) (registered trademark) terminal 72A, a display port (DP) terminal 72B, a digital visual interface (DVI) terminal 72C, a serial digital interface (SDI) terminal 72D, a network interface (IF) 75, a micro processor unit (MPU) 76, a signal input IF 77, a signal processing unit 78, a dynamic random access memory (DRAM) 79, a signal distribution unit 80, and output IFs 81-1 to 81-n.

The local area network (LAN) terminal 71 is, for example, a connection terminal of a LAN cable or the like, and the LAN terminal 71 establishes communication with the personal computer (PC) 30 over a LAN, the personal computer (PC) 30 being operated by the user to supply a control command or the like corresponding to a detail of the operation to the video wall controller 32, and supplies the input control command or the like to the MPU 76 via the network IF 75.

Note that the LAN terminal 71 may have a configuration adapted to physical connection with a wired LAN cable, or may have a configuration adapted to connection with a so-called wireless LAN implemented by wireless communication.

The MPU 76 receives the input of the control command supplied from the PC 30 via the LAN terminal 71 and the network IF 75, and supplies a control signal corresponding to the received control command to the signal processing unit 78. The MPU 76 controls not only the signal processing unit 78 but also the signal input IF 77 and the signal distribution unit 80.

The HDMI terminal 72A, the DP terminal 72B, the DVI terminal 72C, and the SDI terminal 72D each serve as an input terminal of the picture data, and is connected to, for example, the server computer functioning as the video server 31, and supplies the picture signal data to the signal processing unit 78 via the signal input IF 77.

Note that, although FIG. 2 illustrates an example where the video server 31 and the HDMI terminal 72A are connected, any one of the HDMI terminal 72A, the DP terminal 72B, the DVI terminal 72C, or the SDI terminal 72D may be selected and connected as necessary because the HDMI terminal 72A, the DP terminal 72B, the DVI terminal 72C, and the SDI terminal 72D have different standards but basically have similar functions.

The signal processing unit 78 adjusts a magnification/reduction ratio, color temperature, contrast, brightness, white balance, or the like of the picture supplied as the picture data via the signal input IF 77 on the basis of the control signal supplied from the MPU 76, and supplies the resultant picture to the signal distribution unit 80. At this time, the signal processing unit 78 loads the picture data into the connected DRAM 79, performs signal processing based on the control signal, and supplies a result of the signal processing to the signal distribution unit 80 as necessary.

The signal distribution unit 80 distributes the picture data subjected to the signal processing and supplied from the signal processing unit 78, distributes and transmits the picture data to the display units 51-1 to 51-n individually via the output IFs 81-1 to 81-n. Note that some of the output IFs 81-1 to 81-n are not used, in a manner that depends on the size of the video wall 33 including the display units 51. The MPU 76 designates output IFs to be used from among the output IFs 81-1 to 81-n on the basis of the size of the video wall 33, calculates a range of the picture data to be distributed to each output IF to be used, and supplies the calculation result to the signal distribution unit 80. The signal distribution unit 80 distributes the picture data to the output IFs to be used among the output IFs 81-1 to 81-n on the basis of the calculation result from the MPU 76.

The display unit 51 includes a driver control unit 91 and an LED block 92.

The driver control unit 91 supplies, to a plurality of LED drivers 121-1 to 121-M (M represents the number of LED drivers) included in the LED block 92, the picture data for controlling light emission of LEDs constituting LED arrays 122-1 to 122-M.

More specifically, the driver control unit 91 includes a signal input IF 111, a signal processing unit 112, a DRAM 113, and output IFs 114-1 to 114-M.

The signal input IF 111 receives the input of the picture data supplied from the video wall controller 32 and supplies the picture data to the signal processing unit 112.

The signal processing unit 112 corrects color or luminance of each display unit 51 on the basis of the picture data supplied from the signal input IF 111 to generate data for setting light emission intensity of each LED constituting the LED arrays 122-1 to 122-M, and distributes and supplies the data to the LED drivers 121-1 to 121-M of the LED block 92 via the output IFs 114-1 to 114-M.

More specifically, the picture data further contains information such as a length of a blanking interval specified in a general standard. Therefore, with the information such as the length of the blanking interval contained in the picture data taken into account, the signal processing unit 112 generates data for setting the number of LED lines (number of Scan lines), the number of repetitions of light emission (number of repetitions of scanning) during one frame period, and the light emission intensity of each LED constituting the LED arrays 122-1 to 122-M, and distributes and supplies the data to the LED drivers 121-1 to 121-M of the LED block 92 via the output IFs 114-1 to 114-M.

The LED block 92 includes the LED drivers 121-1 to 121-M and the LED arrays 122-1 to 122-M. Note that the LED block is also referred to as LED module.

The LED drivers 121-1 to 121-M each perform pulse width modulation (PWM) control on light emission of LEDs 141 arranged in an array and constituting a corresponding one of the LED arrays 122-1 to 122-M on the basis of the data for setting the light emission intensity of the LEDs 141, the data being contained in the picture data supplied from the driver control unit 91.

### Configuration Example of Led Array

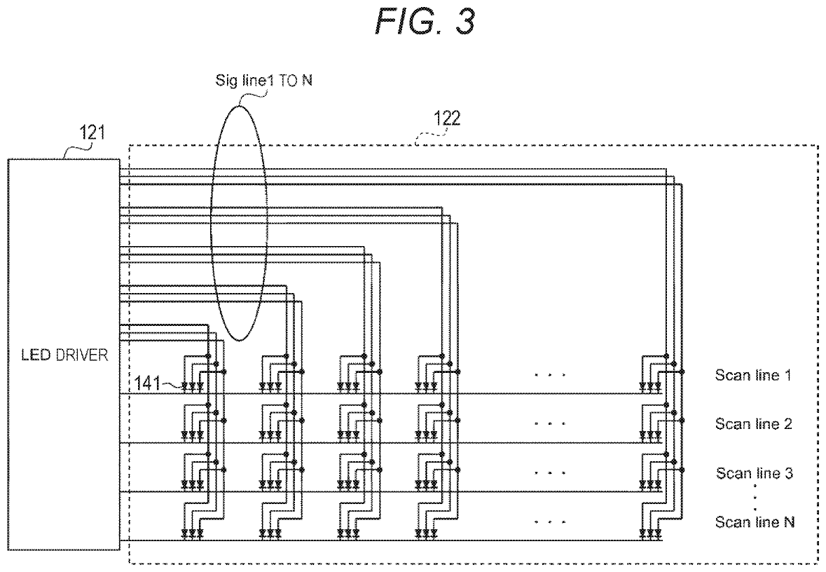

Next, a configuration example of the LED array 122 will be described with reference to FIG. 3. FIG. 3 illustrates a configuration example of the LED array 122 with LED drive connections of a passive-matrix drive type. Therefore, the light emission of the LEDs 141 of the LED array 122 is controlled by a passive matrix drive method.

In the LED array 122 in FIG. 3, LEDs 141 of a common cathode type or common anode type are arranged in an array and are each connected to a Sig line (luminance control wiring line) laid in an up-down direction and a Scan line (row selection wiring line) laid in a left-right direction.

In the LED array 122 in FIG. 3, when a Scan line 1 is set at a predetermined fixed potential to become ON, a current is supplied to the LEDs through the Sig line to bring the LEDs into light emission operation. Note that the predetermined fixed potential is typically, but not limited to, GND=0 V potential.

### Screen Configuration of Video Wall

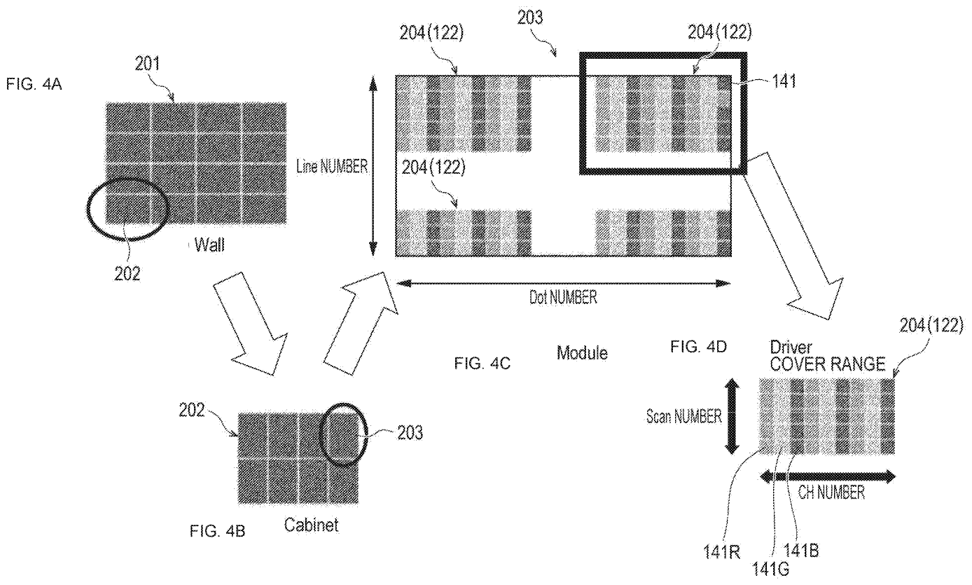

FIG. 4 is a diagram illustrating a screen configuration of the video wall 33. In (A) of FIG. 4, a Wall 201 indicates a screen (display unit, display panel) implemented by the video wall 33 in FIG. 1, and indicates the entire screen on which the picture supplied as the picture data from the video server 31 to the video wall controller 32 is displayed. The Wall 201 also corresponds to a range in which the LEDs 141 (light emitting elements) constituting the screen of the video wall 33 are arranged. A shape of the screen of the Wall 201 is not limited to a specific shape, and is, for example, a shape extending along a flat, curved, or bent surface and having an approximately quadrangular (rectangular) outline. The Wall 201 includes a plurality of separable Cabinets 202 arranged in the up-down and left-right directions. Note that the screen of the Wall 201 may have any shape.

(B) of FIG. 4 is an enlarged view of any one of the plurality of Cabinets 202 constituting the Wall 201 in (A) of FIG. 4. The Cabinets 202 each indicate a section of the screen of the Wall 201, display of the section being controlled by a corresponding one of the display units 51-1 to 51-n in FIG. 1. A shape of the screen (section) of each Cabinet 202 is not limited to a specific shape, and has a shape with a quadrangular outline. The Cabinets 202 can be physically separated from each other, and are, for example, detachably attached to a support (not illustrated) in a predetermined arrangement to constitute the Wall 201. The Cabinets 202 each include a plurality of Modules 203 arranged in the up-down and left-right directions.

(C) of FIG. 4 is diagram illustrating an enlarged view of a part of any one of the plurality of Modules 203 constituting the Cabinet 202 in (B) of FIG. 4. The Modules 203 each indicate a section of the screen (section) of the Cabinet 202, in which a plurality of the LED arrays 122 (and the LED drivers 121) mounted on a single board to be integrated together is arranged. A shape of the screen (section) of each Module 203 is not limited to a specific shape, and has a shape with a quadrangular outline. Separation of the boards on which the LED arrays 122 are mounted causes the Modules 203 to physically separate from each other. For example, at the time of manufacturing, the plurality of LED arrays 122 is arranged in the up-down and left-right directions and mounted on the board corresponding to each Module 203, and the boards are fixed to a support (not illustrated) in a predetermined arrangement to constitute each Cabinet 202. Note that one LED array 122 includes a plurality of the LEDs 141 (LED elements) controlled by one LED driver 121. Assuming that a section on a screen where one LED array 122 is arranged is referred to driver cover range 204 (or driver area), the Modules 203 each include a plurality of the driver cover ranges 204 arranged in the up-down and left-right directions.

(D) of FIG. 4 is an enlarged view of any one of the plurality of driver cover ranges 204 (LED arrays 122) constituting the Module 203 in (C) of FIG. 4. The driver cover ranges 204 (LED arrays 122) each have a configuration in which LEDS 141 (141R, 141G, 141B) for a plurality of pixels are arranged along a line extending in a predetermined line direction (for example, the left-right direction), and LEDs 141 for a plurality of lines are arranged along a scanning direction (for example, the up-down direction) orthogonal to the line direction. The LED 141 of each pixel includes three LEDs 141R, 141G, and 141B that each emit light of a corresponding RGB color wavelength. The LEDs 141R, 141G, and 141B are distinguished and drawn according to a difference in density, and the RGB LEDs 141R, 141G, and 141B for one pixel are arranged along the line direction. How the RGB LEDs 141R, 141G, and 141B for one pixel is arranged, however, is not actually limited to the arrangement along the line direction, and may be an arrangement where the RGB LEDs 141R, 141G, and 141B are arranged adjacent to each other and considered to be arranged on the same line. In a case where the LEDs 141R, 141G, and 141B are not distinguished, the LEDs 141R, 141G, and 141B are simply referred to as LED 141. Assuming that one luminance control wiring line (Sig line in FIG. 3) over which the control signal for controlling the light emission of LEDs 141 arranged in the scanning direction is transmitted is referred to as channel (CH), the number of channels existing in the line direction (left-right direction) (CH number) is equal to three times the number of pixels. The driver cover ranges 204 (LED arrays 122) each include a plurality of the LEDs 141 controlled by one LED driver 121 and arranged in the line direction and the scanning direction. Note that the line direction corresponds to an arrangement direction of LEDs 141 connected to the same row selection wiring line among the plurality of row selection wiring lines (Scan lines) in FIG. 3, and the scanning direction corresponds to a direction orthogonal to the line direction. In a case where the row selection wiring lines are provided along the up-down direction, and the LEDs 141 connected to the same row selection wiring line are arranged in the up-down direction, the line direction corresponds to the up-down direction, and the scanning direction corresponds to the left-right direction. The line direction and the scanning direction may be either the up-down direction or the left-right direction, and the line direction and the scanning direction can be changed in accordance with wiring lines on the boards or a direction in which the boards on which the LED arrays 122 are mounted are installed on the screen.

### Configuration Example of Cabinet

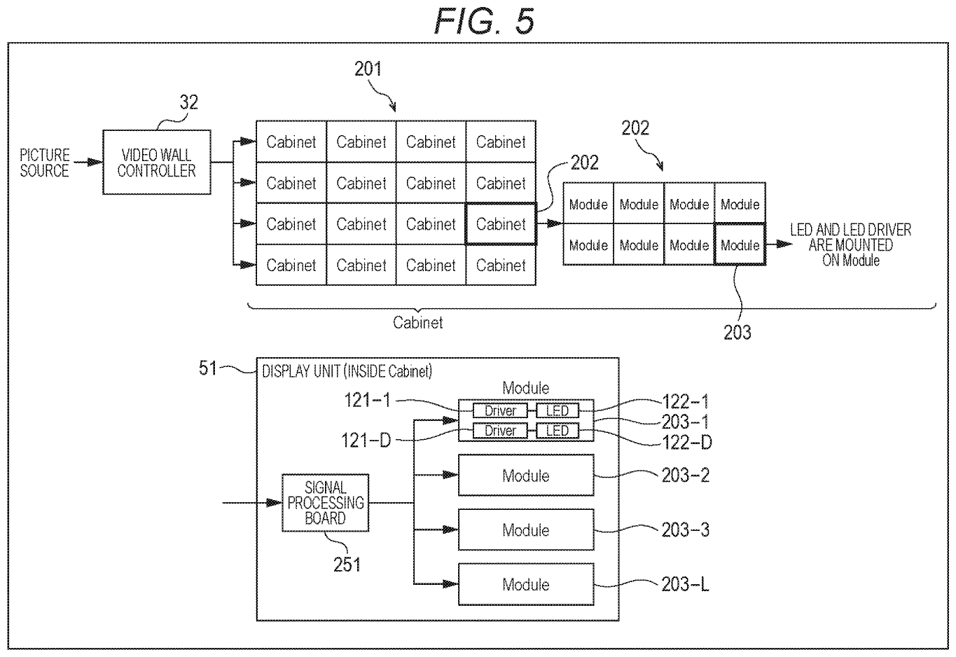

FIG. 5 is a diagram illustrating a configuration related to display control of the Cabinet 202 in FIG. 4. In FIG. 5, picture data (picture source) representing a picture being displayed on the Wall 201 is supplied to the video wall controller 32 illustrated in FIG. 1. The video wall controller 32 generates picture data representing a picture being displayed on each Cabinet 202 on the basis of the supplied picture data. The video wall controller 32 supplies the generated picture data for each Cabinet 202 to the display unit 51 corresponding to the Cabinet 202. The picture being displayed on each Cabinet 202 corresponds to a picture adapted to the section of each Cabinet 202, the section being obtained as a result of dividing the entire image being displayed on the Wall 201 into the respective sections of the Cabinets 202.

Focusing on one Cabinet 202, as illustrated in the lower part of FIG. 5, the display unit 51 corresponding to the Cabinet 202 of interest includes a signal processing board 251 and a plurality of Modules 203-1 to 203-L (L represents the number of Modules 203 belonging to the Cabinet 202). A circuit responsible for performing processing of the driver control unit 91 including the signal processing unit 112 in FIG. 2 is mounted on the signal processing board 251. The Modules 203-1 to 203-L each include a plurality of LED drivers 121-1 to 121-D and LED arrays 122-1 to 122-D (D represents the number of LED arrays 122 constituting each Module 203). Each of the Modules 203-1 to 203-L corresponds to the Module 203 in FIG. 4. The LED arrays 122-1 to 122-D correspond to a plurality of LED arrays 122 that is mounted on the board corresponding to the Module 203 in FIG. 4 and constitutes the screen of the Module 203. The LED drivers 121-1 to 121-D correspond to LED drivers 121 that are mounted on the board corresponding to the Module 203 in FIG. 4 and control the LED arrays 122-1 to 122-D, respectively. In FIG. 2, the LED drivers 121-1 to 121-D and the LED arrays 122-1 to 122-D correspond to D LED drivers 121 mounted on the same board and D LED arrays 122 controlled by the LED drivers 121-1 to 121-D, respectively, among the LED drivers 121-1 to 121-M and the LED arrays 122-1 to 122-M in the LED block 92.

The signal processing board 251 (signal processing unit 112) generates picture data representing a picture being displayed on each of the Modules 203-1 to 203-L on the basis of the picture data supplied from the video wall controller 32. The signal processing unit 112 supplies the picture data generated for each of the Modules 203-1 to 203-L to each of the Modules 203-1 to 203-L.

The picture being displayed on each of the Modules 203-1 to 203-L corresponds to a picture adapted to the section of each of the Modules 203-1 to 203-L, the section being obtained as a result of dividing the picture being displayed on the Cabinet 202 into the respective sections of the Modules 203-1 to 203-L. Moreover, the picture being displayed on each of the Modules 203-1 to 203-L includes a picture being displayed on the section of each of the LED arrays 122-1 to 122-D (each driver cover range 204) of each of the Modules 203-1 to 203-L. The picture data supplied from the signal processing board 251 to each of the Modules 203-1 to 203-L includes picture data representing a picture for each of the LED arrays 122-1 to 122-D, the LED arrays 122-1 to 122-D constituting each of the Modules 203-1 to 203-L. The picture data representing the picture for each of the LED arrays 122-1 to 122-D is supplied to a corresponding one of the LED drivers 121-1 to 121-D corresponding to the LED arrays 122-1 to 122-D. The picture data supplied to the LED drivers 121-1 to 121-D corresponds to, for example, data representing the light emission intensity of each LED 141.

The LED drivers 121-1 to 121-D of each of the Modules 203-1 to 203-L each control the light emission of a corresponding one of the LED arrays 122-1 to 122-D on the basis of the picture data supplied from the signal processing board 251.

### Scanning Control of LED Array

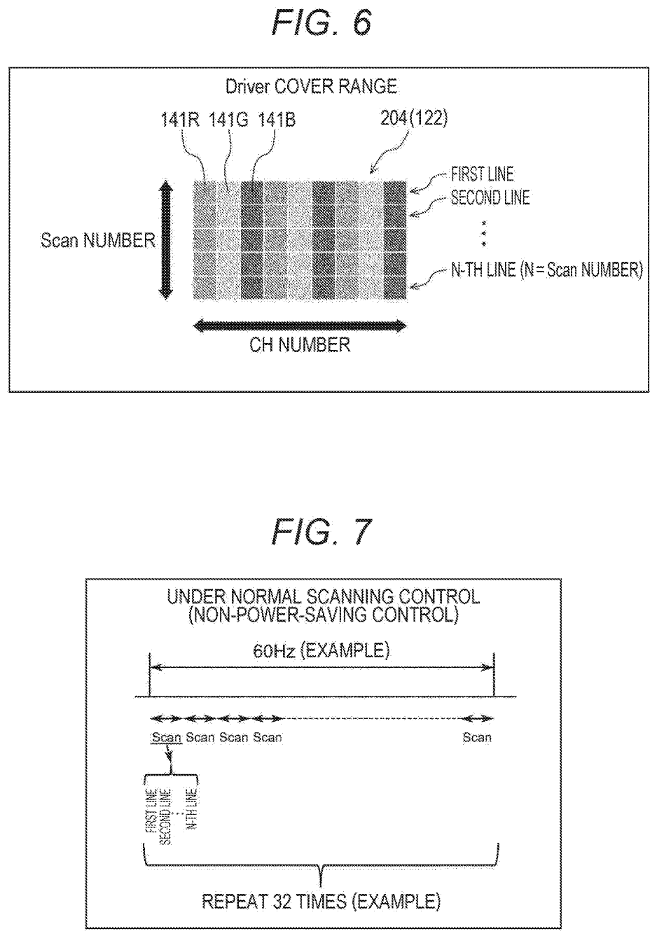

FIG. 6 is a diagram illustrating a configuration of one LED array 122 (driver cover range 204). Note that the LED array 122 in FIG. 6 is an enlarged view of the LED array 122 illustrated in (D) of FIG. 5, and parts corresponding to the LED array 122 illustrated in (D) of FIG. 5 are denoted by the same reference numerals, and no detailed description of the parts will be given.

In FIG. 6, in the LED array 122 (driver cover range 204), RGB LEDs 141R, 141G, and 141B constituting one pixel are arranged for a plurality of pixels in the line direction (left-right direction) and the scanning direction (up-down direction). Assuming that the LEDs 141R, 141G, and 141B of the same pixel are arranged in the same line, the LED array 122 include LEDs 141 along the line direction for the number of channels (CH number) that is three times the number of pixels arranged in the line direction, and includes LEDs 141 along the scanning direction for the number of lines (1 to N lines) equal to as the number of pixels arranged in the scanning direction.

The LED driver 121 that controls the light emission of the LED array 122 scans the LED array 122 to control on/off of the light emission of each LED 141 of the LED array 122. When scanning the LED array 122, the LED driver 121 sequentially switches a line being controlled at predetermined time intervals (line control time intervals) from the first line to the N-th line, for example. The LED driver 121 controls a light emission time of the LED 141 of each channel of the line being controlled on the basis of the picture data supplied from the signal processing unit 112. Specifically, the control of the light emission time corresponds to control of a ratio of a period during which the light emission is on to a period during which the light emission is off in the line control time. Each LED driver 121 repeats such scanning of the LED array 122 a plurality of times during one frame period that is a time interval at which the picture data supplied to the LED driver 121 is updated.

### Normal Scanning Control

FIG. 7 is a diagram for describing normal scanning control of the LED array 122 performed by the LED driver 121. In FIG. 7, a horizontal axis represents time. In a case where a frame rate of the picture data supplied to the video wall controller 32 is 60 FPS, the picture data supplied from the signal processing unit 112 (see FIG. 2) to the LED driver 121 is updated every 1/60 seconds, the update timing is 60 Hz, and the period of the update timing (one frame period) is 1/60 seconds. The period of 60 Hz shown on the horizontal axis indicates a time length (1/60 seconds) corresponding to one frame period. Under the normal scanning control, the LED driver 121 repeats the scanning of the LED array 122, for example, 32 times during one frame period (1/60 seconds) from when the picture data supplied from the signal processing unit 112 is updated to when the picture data is updated next. The LED driver 121 controls the light emission time of each LED 141 of the line being controlled (the light emission time of each LED 141 during the line control time) at the time of each scanning. As a result, the LED array 122 is controlled so as to make the light emission intensity of each LED 141 during one frame period equal to the light emission intensity corresponding to the picture data supplied to the LED driver 121.

### Description of Present Technology

The present technology is to reduce power consumption of the video wall 33 by reducing the frequency of scanning (the number of repetitions of scanning during one frame period) of the LED array 122 where a region regarded as a still image of the picture data supplied to the video wall controller 32 is displayed. The region regarded as a still image has almost no influence on picture quality even if the frequency of scanning is reduced.

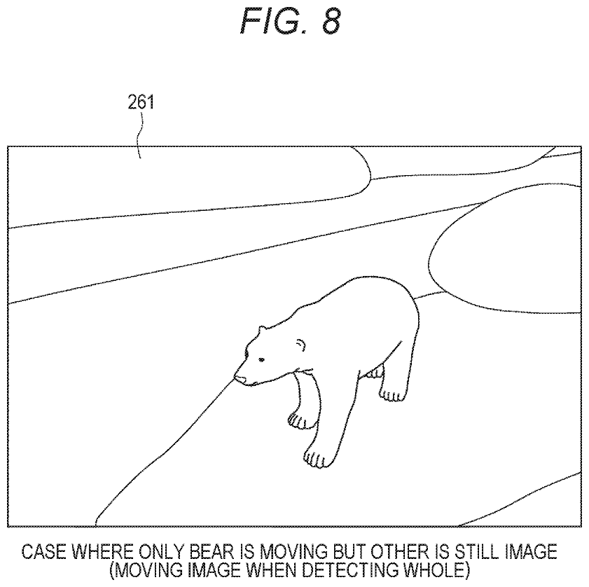

FIG. 8 is a diagram illustrating an example of a picture supplied as picture data to the video wall controller 32. It is assumed that a bear appears in a picture 261 in FIG. 8 and the bear image is moving in the picture 261. It is assumed that an image (background image) other than the bear appearing in the picture 261 is nearly stationary in the picture 261.

In this case, when a determination is made as to whether or not the picture 261 is a moving image that changes with time or a still image that does not change with time, the bear image is moving in the picture 261, so that it is determined that the picture is a moving image.

The determination as to whether or not the picture is a moving image or a still image is made, for example, by comparing images of two temporally preceding and following frames (two frames captured at different times). The images of two temporally preceding and following frames correspond to, for example, an image of the latest (current) frame (following frame) and an image of a frame (preceding frame) one frame or a plurality of frames before the current frame, both the frames being supplied to the video wall controller 32 as picture data. For the image of the preceding frame and the image of the following frame, an amount of change in pixel value between corresponding pixels (difference in pixel value at the same position) is calculated, and the total amount of changes in pixel value of all the pixels is calculated as an amount of change in image, for example. The amount of change in pixel value represents the magnitude of change generated at the position of each pixel between the image of the preceding frame and the image of the following frame. For example, the amount of change in pixel value may be the sum of differences in luminance value of each of RGB between the corresponding pixels or a difference in luminance value indicating brightness between the corresponding pixels, but is not limited to such a value. The picture supplied to the video wall controller 32, that is, the picture being displayed on the Wall 201 is determined to be a moving image when the calculated amount of change in image is greater than or equal to a predetermined threshold, and is determined to be a still image when the calculated amount of change in image is less than the predetermined threshold.

In a case where a determination is made as to whether or not the picture is a still image or a moving image by calculating the total amount of changes in pixel value of all the pixels as the amount of change in image as described above, when a change occurs in a part of the image (the bear image) in the picture 261 as in the picture 261 in FIG. 8, the entire picture 261 is determined to be a moving image, and the frequency of scanning, therefore, cannot be reduced.

In the present technology, a determination is made as to whether or not the picture being displayed on the Wall 201 is a still image or a moving image for each image region obtained by dividing the entire picture into a plurality of image regions, and only the frequency of scanning of an LED array corresponding to an image region determined to be a still image is reduced. This allows, even when the picture is a moving image as a whole, a reduction in power consumption of the video wall 33 without deteriorating picture quality.

### Description of Still Image Determination Section

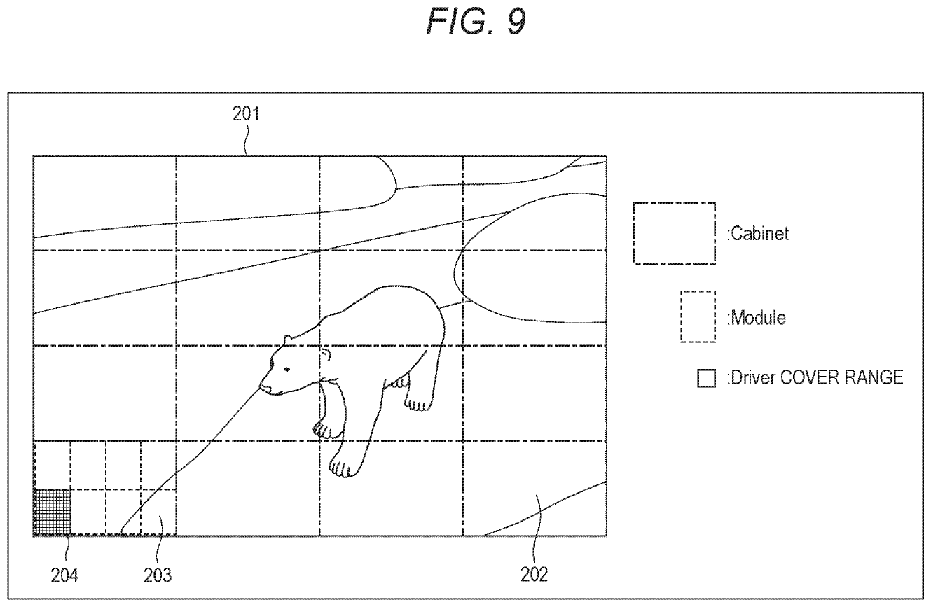

FIG. 9 is a diagram illustrating a region where the amount of change in image is determined according to the present technology. FIG. 9 illustrates the sections of the Cabinets 202, the sections of the Modules 203, and the sections of the driver cover ranges 204 (LED arrays 122) of the screen of the Wall 201 on which the picture 261 in FIG. 8 is displayed.

In the normal calculation of the amount of change in image described with reference to FIG. 8, the total amount of changes in pixel value of the pixels corresponding to the entire range of the picture 261 (images of two temporally preceding and following frames) is calculated as the amount of change in image. On the other hand, it is assumed that the total amount of changes in pixel value of pixels of an image being displayed in each section is calculated as the amount of change in image for each section of the Cabinets 202, for each section of the Modules 203, or for each section of the driver cover ranges 204 (LED arrays 122). Note that a section on the screen of the Wall 201 indicating a pixel range for which the total amount of changes in pixel value is calculated as the amount of change in image is referred to as still image determination section. At this time, in a case where the amount of change in image is calculated for each section of the Cabinets 202, for each section of the Modules 203, or for each section of the driver cover ranges 204 (LED arrays 122), the still image determination section corresponds to each section of the Cabinets 202, each section of the Modules 203, or each section of the driver cover ranges 204 (LED arrays 122).

In a case where the total amount of changes in pixel value is calculated as the amount of change in image of each still image determination section, an image in the still image determination section having the amount of change in image greater than or equal to the predetermined threshold is determined to be a moving image, and an image in the still image determination section having the amount of change in image less than the predetermined threshold is determined to be a still image. The present technology allows a reduction in frequency of scanning of an LED array 122 that falls within the still image determination section determined to be a still image as described above as compared with the normal scanning control.

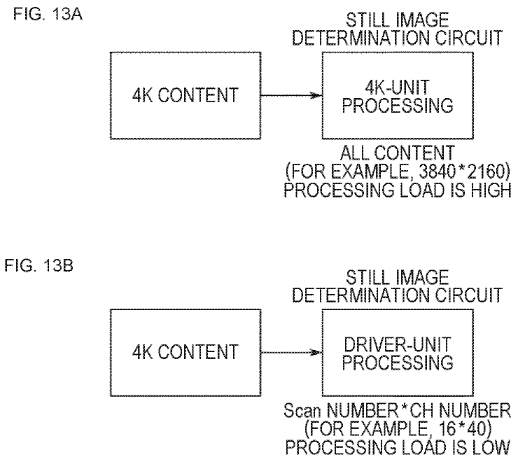

The still image determination section may be any one of each section of the Cabinets 202, each section of the Modules 203, or each section of the driver cover ranges 204 (LED arrays 122); however, the larger the still image determination section, the larger the processing load on an arithmetic processing unit for calculating the amount of change in image of each still image determination section, and the larger a circuit scale of the arithmetic processing unit, but the number of arithmetic processing units becomes smaller. On the other hand, the smaller the still image determination section, the larger the number of arithmetic processing units, but the processing load on the arithmetic processing unit for calculating the amount of change in image of each still image determination section becomes smaller, and the circuit scale becomes smaller accordingly. For example, in a case where the picture being displayed on the Wall 201 as illustrated in (A) of FIG. 13 is a 4K content picture, it is assumed that the total amount of changes in pixel value of the pixels of the entire range of the picture is calculated as the amount of change in image, and a determination is made as to whether or not the picture is a still image or a moving image. In this case, a circuit (still image determination circuit) for this purpose needs to process, for example, data for 3840×2160 pixels and the processing load becomes enormous accordingly. On the other hand, as illustrated in (B) of FIG. 13, it is assumed that each section of the driver cover ranges 204 (LED arrays 122) is set as the still image determination section, the amount of change in image is calculated, and a determination is made as to whether or not the section is a still image or a moving image. In this case, the still image determination circuit for this purpose is only required to process, for example, data for 16×40 pixels (an example of the number of pixels of one LED array 122), and the processing load becomes extremely small accordingly.

Furthermore, the larger the still image determination section, the smaller a proportion of a region determined to be a still image to the entire screen of the Wall 201, which reduces the effect of reducing power consumption. The smaller the still image determination section, the larger the proportion of the region determined to be a still image to the entire screen of the Wall 201, which enhances the effect of reducing power consumption. That is, in FIG. 9, in a case where the still image determination section is defined as each section of the Cabinets 202, a total of 10 sections of the Cabinets 202 including sections located at both the left and right ends, and sections located at the upper end where no bear image appears, are each determined to be a still image. On the other hand, in a case where the still image determination section is defined as each section of the Modules 203, there are sections of the Modules 203 each determined to be a still image in addition to the total of 10 sections of the Cabinets 202 including the sections located at both the left and right ends, and sections located at the upper end where no bear image appears. For example, in four sections of the Cabinets 202 located at the center where the bear image appears and two sections of the Cabinets 202 located below the four sections, sections of the Cabinets 202 where no bear image appears are determined to be a still image.

### Configuration Related to Change of Frequency of Scanning of LED Array

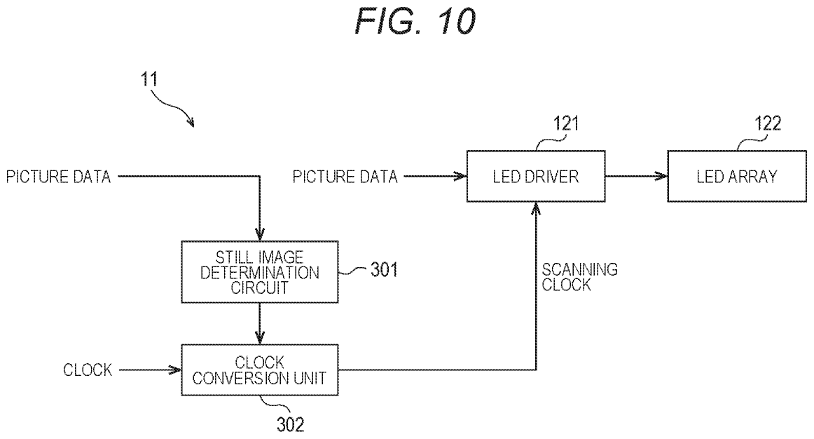

FIG. 10 is a block diagram illustrating extracted components, according to the present technology, of the display system 11 in FIGS. 1 and 2. In FIG. 10, an LED driver 121 and an LED array 122 indicate an LED driver 121 of interest that is any one of the LED drivers 121-1 to 121-M in FIG. 2, and an LED array 122 of interest that is any one of the LED arrays 122-1 to 122-M in FIG. 2, respectively. The LED driver 121 and the LED array 122 indicate an LED driver and an LED array included in a Module 203 of interest that is any one of the Modules 203-1 to 203-L in FIG. 5, and indicates an LED driver of interest that is any one of the LED drivers 121-1 to 121-D included in the Module 203 of interest and an LED array of interest that is any one of the LED arrays 122-1 to 122-D included in the Module 203 of interest, respectively. Note that the present technology is not limited to a case where the entire screen can be separated into a plurality of Cabinets 202, and the entire screen may be a single screen. For example, the present technology is also applicable to a case where the video wall 33 includes a single display unit 51 rather than the plurality of display units 51. Furthermore, in a case where the still image determination section corresponds to each section of the driver cover ranges 204 (LED arrays 122), the present technology is also applicable to a case where the screen is not divided into the sections of the Modules 203.

In FIG. 10, the display system 11 includes a still image determination circuit 301 and a clock conversion unit 302. The still image determination circuit 301 and the clock conversion unit 302 can be arranged at any place such as the video wall controller 32, the driver control unit 91 or the LED block 92 of the display unit 51, or the board corresponding to each Module 203, and processing performed by the still image determination circuit 301 and the clock conversion unit 302 can be a part of the processing performed by the signal processing unit 78 of the video wall controller 32, the signal processing unit 112 of the driver control unit 91, or the like.

The still image determination circuit 301 acquires picture data representing an image being displayed within the range of the still image determination section including the section of the LED array 122 of interest or an image within a range including the image within the range. For example, the still image determination circuit 301 is provided for each still image determination section, and in a case where the still image determination section corresponds to each section of the Cabinets 202, the still image determination circuit 301 acquires picture data being displayed in the section of a Cabinet 202 including the section of the LED array 122 of interest. Specifically, among pieces of picture data supplied from the video wall controller 32 to the display units 51-1 to 51-n in FIGS. 1 and 2, the still image determination circuit 301 acquires picture data supplied to a display unit 51 including the LED array 122 of interest (Module 203 of interest). In this case, the still image determination circuit 301 may serve as a processing unit incorporated in the signal processing unit 78 of the video wall controller 32 to acquire picture data in the video wall controller 32. The still image determination circuit 301 may be arranged for each display unit 51 (Cabinet 202), and may serve as a processing unit installed in the display unit 51 (driver control unit 91) including the LED array 122 of interest or incorporated in the signal processing unit 112 to acquire picture data. The still image determination circuit 301 may acquire picture data in a device separate from the video wall controller 32 and the display unit 51. Note that the still image determination circuit 301 may acquire picture data (picture data representing an image being displayed within the range of the Wall 201) supplied from the video server 31 to the video wall controller 32.

In a case where the still image determination section corresponds to each section of the Modules 203, the still image determination circuit 301 acquires picture data being displayed in the section of a Module 203 including the section of the LED array 122 of interest. Specifically, among pieces of picture data supplied from the signal processing unit 112 of the display unit 51 including the LED array 122 of interest in FIG. 2 to the LED arrays 122-1 to 122-M, pieces of picture data supplied to all the LED arrays 122 (including the LED array 122 of interest) included in the Module 203 of interest are acquired. In this case, the still image determination circuit 301 may serve as a processing unit installed in the driver control unit 91 or incorporated in the signal processing unit 112 to acquire picture data. Alternatively, the still image determination circuit 301 may be mounted (arranged) on the board corresponding to each Module 203 (board on which the LED arrays 122 and the like are mounted) and acquire picture data supplied from the signal processing unit 112 to all the LED arrays 122 of the Module 203 of interest. Note that the still image determination circuit 301 may acquire picture data (picture data representing an image being displayed within the range of the section of a Cabinet 202 including the section of the Module 203 of interest) supplied from the video wall controller 32 to the display unit 51 including the LED array 122 of interest.

In a case where the still image determination section corresponds to each section of the driver cover ranges 204 (LED arrays 122), the still image determination circuit 301 acquires picture data being displayed in the section of the LED array 122 of interest. Specifically, among pieces of picture data supplied from the signal processing unit 112 of the display unit 51 including the LED array 122 of interest in FIG. 2 to the LED arrays 122-1 to 122-M, picture data supplied to the LED array 122 of interest is acquired. In this case, the still image determination circuit 301 may serve as a processing unit installed in the driver control unit 91 or incorporated in the signal processing unit 112 to acquire picture data. Alternatively, the still image determination circuit 301 may be mounted on a board corresponding to the Module 203 of interest (board on which the LED arrays 122 and the like are mounted) and acquire picture data supplied from the signal processing unit 112 to the LED array 122 of interest of the Module 203 of interest. Note that the still image determination circuit 301 may acquire picture data supplied from the video wall controller 32 to the display unit 51 including the LED array 122 of interest (picture data representing an image being displayed within the range of the Wall 201), or may acquire picture data supplied from the signal processing unit 112 to all the LED arrays 122 of the Module 203 of interest (picture data representing an image being displayed within the range of the section of the Cabinet 202 including the section of the Module 203 of interest).

The still image determination circuit 301 calculates, on the basis of the acquired picture data, the amount of change in image of the still image determination section including the section of the LED array 122 of interest. That is, the still image determination circuit 301 calculates, on the basis of the acquired picture data, the amount of change in pixel value of each pixel being displayed in the still image determination section between the image of the current (following) frame and the image of the preceding frame. The still image determination circuit 301 calculates the total amount of changes in pixel value of the pixels being displayed in the still image determination section as the amount of change in image of the still image determination section. In a case where the calculated amount of change in image of the still image determination section is greater than or equal to the predetermined threshold, the still image determination circuit 301 determines that the image being displayed within the range of the still image determination section is a moving image. In a case where the calculated amount of change in image of the still image determination section is less than the predetermined threshold, the still image determination circuit 301 determines that the image being displayed within the range of the still image determination section is a still image. The still image determination circuit 301 supplies the determination result to the clock conversion unit 302.

The clock conversion unit 302 acquires a clock signal generated by a clock generation circuit (not illustrated), converts the frequency of the acquired clock signal by a factor of one or a predetermined factor on the basis of the determination result from the still image determination circuit 301, and supplies the converted clock signal to the LED driver 121 of interest. The frequency of the clock signal supplied from the clock conversion unit 302 to the LED driver 121 corresponds to the number of times of scanning of the LED array 122 repeated per second. As described in FIG. 7, in a case where the frame rate of the picture data supplied to the video wall controller 32 is 60 FPS, the picture data supplied from the signal processing unit 112 to the LED driver 121 is updated every 1/60 seconds, the update timing is 60 Hz, and the period of the update timing (one frame period) is 1/60 seconds. Under the normal scanning control, the LED driver 121 repeats the scanning of the LED array 122 32 times during a period of 1/60 seconds that is one frame period, so that the scanning is performed at a frequency of 32×60 (=1920) times per second. Note that the number of times of scanning repeated per second is referred to as scanning frequency. At this time, the frequency of the clock signal supplied to the LED driver 121 is assumed to be 32×60 (=1920) Hz that is the same as the scanning frequency. For example, when the frequency of the clock signal supplied from the clock generation circuit is 32×60 (=1920) Hz, the clock conversion unit 302 supplies the clock signal supplied from the clock generation circuit to the LED driver 121 as it is without converting the frequency under the normal scanning control. This causes the LED driver 121 to repeat the scanning of the LED array 122 32 times during a period of 1/60 seconds that is one frame period. Here, the normal scanning control corresponds to scanning control performed on the LED array 122 included in the still image determination section in a case where the determination result from the still image determination circuit 301 indicates a moving image. Under the normal scanning control, power consumption required for the light emission control of the LED array 122 included in the still image determination section is not reduced. Note that the frequency of scanning (the number of repetitions of scanning during one frame period, or the scanning frequency) of the LED array 122 under the normal scanning control is not limited to a specific frequency, and the frequency of the clock signal supplied from the clock generation circuit to the clock conversion unit 302 is not limited to a specific frequency as well. The clock conversion unit 302 may convert the frequency of the clock supplied from the clock generation circuit into a scanning frequency in accordance with the frequency of scanning of the LED array 122 under the normal scanning control and supply the scanning frequency to the LED driver 121.

In a case where the determination result from the still image determination circuit 301 indicates a still image, the clock conversion unit 302 reduces the frequency of the clock signal supplied to the LED driver 121 stepwise from the frequency under the normal scanning control. The reduction in the frequency of the clock signal supplied to the LED driver 121 causes a reduction in the frequency of scanning of the LED array 122, and power consumption required for the LED driver 121 to control the light emission of the LED array 122 is reduced accordingly.

The LED driver 121 controls the frequency of scanning of the LED array 122 in accordance with the frequency of the clock signal supplied from the clock conversion unit 302. The LED driver 121 controls the light emission time of each LED 141 of the line being controlled at the time of each scanning on the basis of the picture data supplied from the signal processing unit 112 in FIG. 2 (picture data representing an image being displayed within the range of the section of the LED array 122).

### Transition from Normal State to Power-Saving State

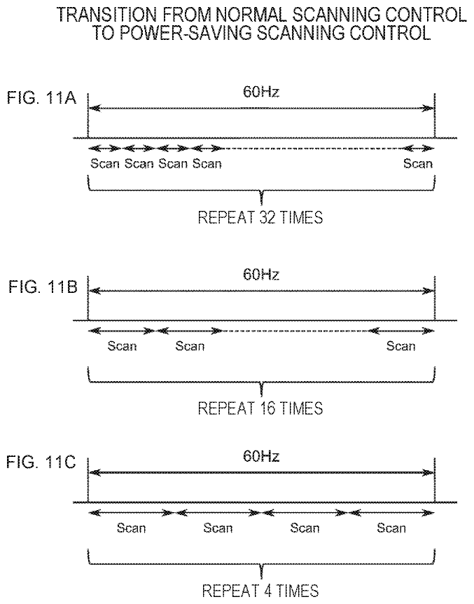

FIG. 11 is a diagram for describing transition from the normal scanning control to power-saving scanning control of the LED array 122. A of FIG. 11 is a diagram illustrating the scanning of the LED array 122 in the normal state, and the scanning is repeated 32 time during one frame period (1/60 seconds), in a manner similar to the description given with reference to FIG. 7. At this time, it is assumed that the clock conversion unit 302 supplies, to the LED driver 121, the clock signal of 32×60 (=1920) Hz that is the same as the scanning frequency as described above.

In a case where the determination result from the still image determination circuit 301 indicates a still image, the clock conversion unit 302 converts the frequency of the clock signal of 32×60 (=1920) Hz supplied from the clock generation circuit by a factor of 1/2, and supplies the clock signal of 16×60 (=960) Hz to the LED driver 121. This causes, as illustrated in B of FIG. 11, the LED driver 121 to repeat the scanning of the LED array 122 16 times during one frame period (1/60 seconds). As a result, the frequency of scanning of the LED array 122 (the number of repetitions of scanning during one frame period, or the scanning frequency) is reduced to half the previous state (normal scanning control).

In a case where the frequency of scanning of the LED array 122 is reduced to half the case of the normal scanning control, and then the determination result from the still image determination circuit 301 indicates a still image, the clock conversion unit 302 converts the frequency of the clock signal of 32×60 (=1920) Hz supplied from the clock generation circuit by a factor of ¼ that is the square of ½, and supplies the clock signal of 8×60 (=480) Hz to the LED driver 121. Although not illustrated in FIG. 11, in this case, the LED driver 121 repeats the scanning of the LED array 122 eight times during one frame period (1/60 seconds). As a result, the frequency of scanning of the LED array 122 is reduced to half the previous state (state of B of FIG. 11).

In a case where the frequency of scanning of the LED array 122 is reduced to ¼ the case of the normal scanning control, and then the determination result from the still image determination circuit 301 indicates a still image, the clock conversion unit 302 converts the frequency of the clock signal of 32×60 (=1920) Hz supplied from the clock generation circuit by a factor of ⅛ that is the cube of ½, and supplies the clock signal of 4×60 (=240) Hz to the LED driver 121. This causes, as illustrated in C of FIG. 11, the LED driver 121 to repeat the scanning of the LED array 122 four times during one frame period (1/60 seconds). As a result, the frequency of scanning of the LED array 122 is reduced to half the previous state.

As described above, in a case where a state where (time during which) the determination result from still image determination circuit 301 indicates a still image continues, the clock conversion unit 302 reduces the frequency of the clock signal supplied to LED driver 121 stepwise by a factor of ½ while the state continues. As a result, the frequency of scanning of the LED array 122 is reduced stepwise by half (a factor of ½). This causes a gradual reduction in power consumption required for the LED driver 121 to control the light emission of the LED array 122. Note that a reduction amount for one step when the frequency of scanning is reduced stepwise may be set to any desired amount.

In a case where the frequency of scanning (the number of repetitions of scanning during one frame period) is reduced from a predetermined maximum value (in the normal state) to a minimum value (for example, two times), the clock conversion unit 302 maintains the frequency of the clock signal supplied to the LED driver 121 and does not reduce the frequency of scanning any more.

In a case where control other than normal scanning control is enabled, and the determination result from the still image determination circuit 301 indicates is a moving image, the clock conversion unit 302 may employ the following aspect. As a first aspect, the clock conversion unit 302 immediately returns the frequency of the clock signal supplied to the LED driver 121 to the frequency applied under the normal scanning control. As a result, the frequency of scanning of the LED array 122 (the number of repetitions of scanning during one frame period) is returned to the maximum value under the normal scanning control. As a second aspect, in a case where a state where the determination result from the still image determination circuit 301 indicates a moving image continues, and the duration of the state is less than or equal to a predetermined threshold, the clock conversion unit 302 maintains the frequency of the clock signal supplied to the LED driver 121 at the current frequency.

As a result, the frequency of scanning is also maintained at the current frequency of scanning. In a case where the duration of the state indicating a moving image is greater than the predetermined threshold, the clock conversion unit 302 returns the frequency of the clock signal supplied to the LED driver 121 to the frequency applied under the normal scanning control. As a result, the frequency of scanning of the LED array 122 is returned to the maximum value under the normal scanning control. As a third aspect, in a case where the state where the determination result from the still image determination circuit 301 indicates a moving image continues, the clock conversion unit 302 increases the frequency of the clock signal supplied to the LED driver 121 stepwise by, for example, a factor of two. As a result, the frequency of scanning of the LED array 122 is increased stepwise by, for example, a factor of two.

The above is the description given on the assumption that the section of the LED array 122 of interest in FIG. 10 is included in the still image determination section (target still image determination section) that is a section for which the still image determination circuit 301 calculates the amount of change in image. In a case where there are LED arrays 122 included in the target still image determination section other than the LED array 122 of interest, the frequency of scanning of the LED arrays 122 other than the LED array 122 of interest is controlled in the similar manner as the LED array 122 of interest. That is, a clock signal that is the same in frequency as the clock signal output from the clock conversion unit 302 is supplied to all the LED drivers 121 (all the LED drivers 121 corresponding to the LED arrays 122 in the still image determination section) that each control a corresponding one of all the LED arrays 122 (including the LED array 122 of interest) included in the target still image determination section. As the first aspect, a supply source that supplies the clock signal to each LED driver 121 included in the target still image determination section may be a single clock conversion unit 302. As the second aspect, the supply source of the clock signal may be a clock conversion unit that is provided separately for each LED driver 121 and performs processing similar to the processing performed by the clock conversion unit 302. As the third aspect, the supply source of the clock signal may be a plurality of clock conversion units that is each provided for a plurality of LED drivers 121 and performs processing similar to the processing performed by the clock conversion unit 302.

Note that the frequency of scanning of the LED array 122 is not limited to a case where the frequency of scanning is controlled on the basis of the frequency of the clock signal supplied to the LED driver 121. Not only a case where the frequency of scanning of the LED array 122 is controlled on the basis of control data supplied to the LED driver 121 instead of the clock signal, but also other cases may be employed.

### Processing of Changing Frequency of Scanning of LED Array

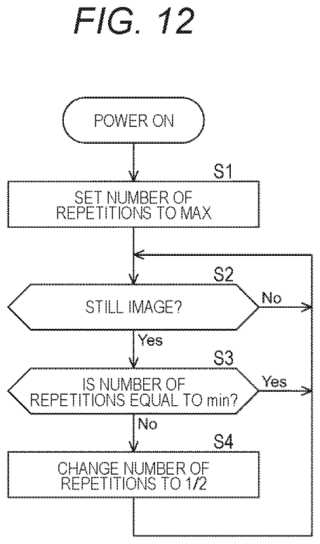

FIG. 12 is a flowchart illustrating a procedure of processing of changing the frequency of scanning of the LED array 122 performed by the clock conversion unit 302 in FIG. 10.

In step S1, the clock conversion unit 302 supplies a clock signal of a maximum frequency under the normal scanning control to the LED driver 121 that controls the LED array 122 included in the still image determination section (target still image determination section) for which the still image determination circuit 301 calculates the amount of change in image. As a result, the frequency of scanning of the LED array 122, that is, the number of repetitions of scanning of the LED array 122 during one frame period is set to the maximum value. The processing proceeds from step S1 to step S2.

In step S2, the clock conversion unit 302 determines whether or not the image being displayed within the range of the target still image determination section is a still image on the basis of the determination result from still image determination circuit 301. In a case of negative determination in step S2, the processing repeats step S2. In a case of affirmative determination in step S2, the processing proceeds to step S3.

In step S3, the clock conversion unit 302 determines whether or not the frequency of the clock signal supplied to the LED driver 121 is equal to a minimum value. That is, it is determined whether or not the number of repetitions of scanning of the LED array 122 during one frame period is equal to the predetermined minimum value. In a case of affirmative determination in step S3, the processing returns to step S2. That is, the clock conversion unit 302 never changes the frequency of scanning of the LED array 122 without changing the frequency of the clock signal supplied to the LED driver 121. In a case of negative determination in step S3, the processing proceeds to step S4.

In step S4, the clock conversion unit 302 changes the frequency of the clock signal supplied to the LED driver 121 to ½ times the current frequency to reduce the number of repetitions of scanning of the LED array 122 during one frame period to ½. The processing returns from step S4 to step S2, and is repeated from step S2. Note that the present flowchart illustrates an aspect where the frequency of scanning of the LED array 122 is not changed in a case of negative determination in step S2, that is, in a case where the determination result from the still image determination circuit 301 indicates that the image being displayed within the range of the target still image determination section is a moving image, but it is not limited to such an aspect as described above.

According to the above-described embodiment, a determination is made as to whether or not the picture being displayed on the Wall 201 is a still image or a moving image for each image region (section image or section picture) obtained by dividing the entire picture into a plurality of image regions, and the frequency of scanning of the LED array corresponding to the image region determined to be a still image (the number of times of light emission of each pixel during one frame period) is reduced. This allows, even when the picture is a moving image as a whole, a reduction in power consumption of the video wall 33 without deteriorating picture quality. Note that, in the above-described embodiment, in a case where the section image is determined to be a still image, that is, in a case where the amount of change in image of the still image determination section (section image) is less than the threshold, the frequency of scanning of the LED array 122 included in the still image determination section is reduced. In the above-described embodiment, instead of the amount of change in image of the still image determination section, the frequency of scanning of the LED array 122 in each determination section corresponding to the still image determination section may be changed on the basis of the luminance of the section image (section picture) in the determination section. The luminance of the section image corresponds to an evaluation value representing the luminance of each section image. The luminance of the section image may be, for example, a value obtained by adding a luminance value representing the luminance of each pixel, a sum of luminance values of RGB of each pixel, or the like in the determination section, or alternatively, may be an average value, a maximum value, a minimum value, or the like in the determination section. In a case where the luminance of the section image is less than or greater than or equal to a predetermined threshold, the frequency of scanning of the LED array 122 (the number of times of light emission of the LED array 122) in the determination section is reduced. For example, in a case where the section image is bright, when the frequency of scanning of the LED array 122 in the determination section is reduced, a viewer of the picture may feel flickering; on the other hand, in a case where the section image is dark, even when the frequency of scanning is reduced, such a reduction in picture quality is unlikely to occur. In view of this, in a case where the luminance of the section image is less than the threshold, the frequency of scanning of the LED array 122 in the determination section is reduced. On the other hand, in a case where the section image is dark, when the frequency of scanning of the LED array 122 in the determination section is reduced, gradation expression may become inappropriate, but in a case where the section image is bright, even when the frequency of scanning is reduced, the influence on gradation expression is small. In view of this, in a case where the luminance of the section image is greater than or equal to the threshold, the frequency of scanning of the LED array 122 in the determination section may be reduced. Such a reduction in the frequency of scanning based on the luminance of the section image causes a reduction in power consumption of the video wall 33. The change in the frequency of scanning based on the amount of change in image of the section image and the change of the frequency of scanning based on the luminance of the section image can be combined. For example, regarding both the amount of change in image and the luminance of the section image, the frequency of scanning of the LED array 122 is reduced for a determination section that satisfies a condition for reducing the frequency of scanning.

The present technology may also have the following configurations.
(1)

An information processing system including:
an acquisition unit configured to acquire a picture being displayed on a display unit;
a signal processing unit configured to divide the picture acquired by the acquisition unit into section pictures, each of the section pictures being displayed in a corresponding one of a plurality of sections obtained by dividing the display unit;
a determination unit configured to determine an amount of change of each of the section pictures being displayed in a corresponding one of the plurality of sections or luminance of each of the section pictures; and
a setting unit configured to set a frequency of scanning related to light emission of pixels corresponding to each of the section pictures on the basis of the amount of change or the luminance.
(2)

The information processing system according to the above (1), in which
the determination unit calculates the amount of change of each of the section pictures, and
the setting unit sets, in a case where the amount of change is less than a threshold, the frequency of the scanning related to light emission of the pixels corresponding to each of the section pictures to a reduced frequency.
(3)

The information processing system according to the above (1) or (2), in which
the display unit includes a plurality of separable Cabinets, and
the sections each correspond to a section of each of the Cabinets.
(4)

The information processing system according to the above (1) or (2), in which
the display unit includes a plurality of separable Cabinets,
the Cabinets each include a plurality of Modules separable in units of boards on which light emitting elements that emit light of the pixels are mounted, and
the sections each correspond to a section of each of the Modules.
(5)

The information processing system according to the above (1) or (2), in which
the display unit includes a plurality of light emitting element arrays whose light emission is controlled by a plurality of drivers, and
the sections each correspond to a section of each of the light emitting element arrays whose light emission is controlled by the drivers.
(6)

The information processing system according to the above (2), in which
the setting unit reduces the frequency of the scanning stepwise while the amount of change is less than the threshold.
(7)

The information processing system according to any one of the above (1) to (6), in which
the display unit includes a plurality of light emitting element arrays arranged therein, each of the light emitting element arrays having a plurality of light emitting elements arranged therein, each of the light emitting elements being configured to emit light of a corresponding one of the pixels, and
the setting unit sets a frequency of a clock signal supplied to a driver that controls the scanning related to light emission of each of the light emitting element arrays to a frequency corresponding to the frequency of the scanning.
(8)

The information processing system according to any one of the above (1) to (7), in which
the display unit includes a plurality of light emitting element arrays arranged therein, each of the light emitting element arrays having a plurality of light emitting elements arranged therein, each of the light emitting elements being configured to emit light of a corresponding one of the pixels, and
light emission of the light emitting element arrays is controlled by a passive matrix drive method.
(9)

The information processing system according to any one of the above (1) to (8), in which
each of the light emitting elements includes an LED.
(10)

The information processing system according to any one of the above (1) to (9), in which
the setting unit sets the frequency of the scanning as a number of repetitions of the scanning during one frame period of the picture.
(11)

The information processing system according to any one of the above (1) to (10), in which
determination unit is provided for each of the sections.
(12)

The information processing system according to any one of the above (3) to (5), in which
the determination unit is arranged for each of the plurality of Cabinets.
(13)

The information processing system according to the above (4) or (5) 4, in which
the determination unit is arranged for each of the boards of the plurality of Modules.
(14)

The information processing system according to the above (1) or (6), in which
the determination unit calculates the amount of change on the basis of a difference between the section pictures captured at different times.
(15)

The information processing system according to the above (1) or (6), in which
the determination unit calculates the amount of change on the basis of a difference in pixel value at a same position between the section pictures captured at different times.
(16)

The information processing system according to any one of the above (3) to (5), further including
a controller including an acquisition unit configured to acquire the picture being displayed on the display unit, in which
the controller divides the picture into pictures, each of the pictures being displayed on a corresponding one of the plurality of Cabinets, and supplies each of the pictures to a corresponding one of the plurality of Cabinets.
(17)

The information processing system according to the above (1), in which
the determination unit determines luminance of each of the section pictures, and
the setting unit sets the frequency of the scanning related to light emission of the pixels corresponding to each of the section pictures on the basis of the luminance.
(18)

The information processing system according to the above (17), in which
the setting unit sets, in a case where the luminance is less than a threshold, the frequency of the scanning related to light emission of the pixels corresponding to each of the section pictures to a reduced frequency.
(19)

The information processing system according to the above (17), in which
the setting unit sets, in a case where the luminance is greater than or equal to the threshold, the frequency of the scanning related to light emission of the pixels corresponding to each of the section pictures to a reduced frequency.
(20)

An information processing method of an information processing system including an acquisition unit, a signal processing unit, a determination unit, and a setting unit, the information processing method including:
causing the acquisition unit to acquire a picture being displayed on a display unit;
causing the signal processing unit to divide the picture acquired by the acquisition unit into section pictures, each of the section pictures being displayed in a corresponding one of a plurality of sections obtained by dividing the display unit;
causing the determination unit to determine an amount of change of each of the section pictures being displayed in a corresponding one of the plurality of sections or luminance of each of the section pictures; and
causing the setting unit to set a frequency of scanning related to light emission of pixels corresponding to each of the section pictures on the basis of the amount of change or the luminance.

### REFERENCE SIGNS LIST

11 Display system
31 Video server
32 Video wall controller
33 Video wall
51 Display unit
78 Signal processing unit
80 Signal distribution unit
91 Driver control unit
92 LED block
112 Signal processing unit
121 LED driver
141 LED
201 Wall
202 Cabinet
203 Module
204 Driver cover range
251 Signal processing board
301 Still image determination circuit
302 Clock conversion unit

1. An information processing system comprising:
an acquisition unit configured to acquire a picture being displayed on a display unit;
a signal processing unit configured to divide the picture acquired by the acquisition unit into section pictures, each of the section pictures being displayed in a corresponding one of a plurality of sections obtained by dividing the display unit;
a determination unit configured to determine an amount of change of each of the section pictures being displayed in a corresponding one of the plurality of sections or luminance of each of the section pictures; and
a setting unit configured to set a frequency of scanning related to light emission of pixels corresponding to each of the section pictures on a basis of the amount of change or the luminance.

2. The information processing system according to claim 1, wherein
the determination unit calculates the amount of change of each of the section pictures, and
the setting unit sets, in a case where the amount of change is less than a threshold, the frequency of the scanning related to light emission of the pixels corresponding to each of the section pictures to a reduced frequency.

3. The information processing system according to claim 1, wherein
the display unit includes a plurality of separable Cabinets, and
the sections each correspond to a section of each of the Cabinets.

4. The information processing system according to claim 1, wherein
the display unit includes a plurality of separable Cabinets,
the Cabinets each include a plurality of Modules separable in units of boards on which light emitting elements that emit light of the pixels are mounted, and
the sections each correspond to a section of each of the Modules.

5. The information processing system according to claim 1, wherein
the display unit includes a plurality of light emitting element arrays whose light emission is controlled by a plurality of drivers, and
the sections each correspond to a section of each of the light emitting element arrays whose light emission is controlled by the drivers.

6. The information processing system according to claim 2, wherein
the setting unit reduces the frequency of the scanning stepwise while the amount of change is less than the threshold.

7. The information processing system according to claim 1, wherein
the display unit includes a plurality of light emitting element arrays arranged therein, each of the light emitting element arrays having a plurality of light emitting elements arranged therein, each of the light emitting elements being configured to emit light of a corresponding one of the pixels, and
the setting unit sets a frequency of a clock signal supplied to a driver that controls the scanning related to light emission of each of the light emitting element arrays to a frequency corresponding to the frequency of the scanning.

8. The information processing system according to claim 1, wherein
the display unit includes a plurality of light emitting element arrays arranged therein, each of the light emitting element arrays having a plurality of light emitting elements arranged therein, each of the light emitting elements being configured to emit light of a corresponding one of the pixels, and
light emission of the light emitting element arrays is controlled by a passive matrix drive method.

9. The information processing system according to claim 7, wherein
each of the light emitting elements includes an LED.

10. The information processing system according to claim 1, wherein
the setting unit sets the frequency of the scanning as a number of repetitions of the scanning during one frame period of the picture.

11. The information processing system according to claim 1, wherein
the determination unit is provided for each of the sections.

12. The information processing system according to claim 3, wherein
the determination unit is arranged for each of the plurality of Cabinets.

13. The information processing system according to claim 4, wherein
the determination unit is arranged for each of the boards of the plurality of Modules.

14. The information processing system according to claim 1, wherein
the determination unit calculates the amount of change on a basis of a difference between the section pictures captured at different times.

15. The information processing system according to claim 1, wherein
the determination unit calculates the amount of change on a basis of a difference in pixel value at a same position between the section pictures captured at different times.

16. The information processing system according to claim 3, further comprising
a controller including an acquisition unit configured to acquire the picture being displayed on the display unit, wherein
the controller divides the picture into pictures, each of the pictures being displayed on a corresponding one of the plurality of Cabinets, and supplies each of the pictures to a corresponding one of the plurality of Cabinets.

17. The information processing system according to claim 1, wherein
the determination unit determines luminance of each of the section pictures, and
the setting unit sets the frequency of the scanning related to light emission of the pixels corresponding to each of the section pictures on a basis of the luminance.

18. The information processing system according to claim 17, wherein
the setting unit sets, in a case where the luminance is less than a threshold, the frequency of the scanning related to light emission of the pixels corresponding to each of the section pictures to a reduced frequency.

19. The information processing system according to claim 17, wherein
the setting unit sets, in a case where the luminance is greater than or equal to the threshold, the frequency of the scanning related to light emission of the pixels corresponding to each of the section pictures to a reduced frequency.

20. An information processing method of an information processing system including an acquisition unit, a signal processing unit, a determination unit, and a setting unit, the information processing method comprising:
causing the acquisition unit to acquire a picture being displayed on a display unit;
causing the signal processing unit to divide the picture acquired by the acquisition unit into section pictures, each of the section pictures being displayed in a corresponding one of a plurality of sections obtained by dividing the display unit;
causing the determination unit to determine an amount of change of each of the section pictures being displayed in a corresponding one of the plurality of sections or luminance of each of the section pictures; and
causing the setting unit to set a frequency of scanning related to light emission of pixels corresponding to each of the section pictures on a basis of the amount of change or the luminance.
